(19) United States
(12) Patent Application Publication
(10) Pub. No.: US 2004/0142562 A1
(43) Pub. Date: Jul. 22, 2004

(54) Method of fabricating a shallow trench isolation structure

(76) Inventors: Zhen-Long Chen, Tainan Hsien (TW); Ping-Wei Lin, Hsinchu (TW); Chun-Feng Nieh, Hsinchu Hsien (TW); Fung-Hsu Cheng, Taoyuan (TW)

Correspondence Address: BIRCH STEWART KOLASCH & BIRCH, PO BOX 747, FALLS CHURCH, VA, 22040-0747, US

(21) Appl. No.: 10/345,326

(22) Filed: Jan. 16, 2003

(51) Int. Cl. H01L 21/302; H01L 21/461; H01L 21/311

(52) U.S. Cl. 438/689

(57) ABSTRACT

A method of fabricating a well-filled STI Structure in a semiconductor substrate. A trench is formed in the semiconductor substrate. A liner oxide and a liner nitride are formed on the bottom and sidewall of the trench subsequently. A HDP oxide layer is deposited in the trench conformally to fill a portion of the trench. A layer of poly-silicon is deposited over the HDP oxide layer conformally. The semiconductor substrate is subjected to a thermal treatment to oxidize the poly-silicon. The surface of the semiconductor substrate is planarized to form a shallow trench isolation structure. The trench is well filled by the oxidized poly-silicon and the HDP oxide without voids and seams.

### BACKGROUND OF THE INVENTION

1. Field of the Invention

The present invention relates to a method for forming a semiconductor device. More particularly, the present invention relates to a method for fabricating a shallow trench isolation (STI) structure.

2. Description of the Related Art

Advances in the production of integrated circuits have led to an increase in the level of integration and the miniaturization of semiconductor devices. As the level of integration increases, both the dimensions of each device and size of the isolating structures between devices are reduced. Consequently, device isolation structures are increasingly harder to form. A device isolation structure such as a field oxide layer formed by local oxidation (LOCOS) is no longer suitable for small dimensional devices due to the intensification of bird's beak encroachment. Therefore, the shallow trench isolation (STI) method has been developed for highly integrated circuits, and, in particular, sub-half micron integrated circuits.

A typical process for shallow trench isolation fabrication generally includes the following steps. First, a shallow trench is formed in a semiconductor substrate by selective etching. Second, an insulating layer is deposited on the entire surface of the semiconductor substrate to fill the trench. The insulating layer is typically formed of silicon dioxide by chemical vapor deposition (CVD), such as atmospheric pressure chemical vapor deposition (APCVD), sub-atmospheric pressure chemical vapor deposition (SACVD) or high density plasma CVD (HDPCVD). Finally, CMP is used to planarize the insulating layer, thus the insulating layer remaining in the trench serves as a STI region.

Because of the increasing complexity of electronic devices, the dimensions of semiconductor devices are shrinking, while the width of STI regions is decreasing to 0.11 μm or less, and the aspect ratio of STI regions is increasing beyond 3. Even if a HDPCVD with good filling capability is employed, voids or seams still exist in the STI regions as shown in FIG. 3 and one-step coverage is hard to achieve. When conductive materials are deposited in subsequent processes, these defects cause short circuits between devices, thus reducing the lifetime of the device.

### BRIEF SUMMARY OF THE INVENTION

The object of the present invention is to solve the above-mentioned problems and to provide a method of fabricating a shallow trench isolation structure with improved gap filling capability.

To achieve the above-mentioned object, the present invention provides a method of fabricating a shallow trench isolation structure, comprising the following steps. A trench is formed in the semiconductor substrate and a liner oxide is formed on the bottom and sidewall of the trench. An oxide layer is deposited in the trench conformally to fill a portion of the trench by high density plasma chemical vapor deposition (HDPCVD). A layer of poly-silicon is deposited over the oxide layer conformally to fill the trench. The semiconductor substrate is subjected to a thermal treatment to oxidize the poly-silicon. The surface of the semiconductor substrate is planarized to form a shallow trench isolation structure.

According to the method of the present invention, after the thermal treatment, the poly-silicon is oxidized to form good insulating oxide without seams or voids in the STI structure. The HDP oxide underlying the poly-silicon prevents silicon sidewall of the trench from being oxidized in thermal treatment, which may lead to current leakage of semiconductor devices. Preferably, before the HDP oxide deposition, a liner nitride is formed over the liner oxide to further protect the semiconductor substrate from subsequent thermal oxidation.

### BRIEF DESCRIPTION OF THE DRAWINGS

The present invention will become more fully understood from the detailed description given herein below and the accompanying drawings, given by way of illustration only and thus not intended to be limitative of the present invention. In the drawings,

FIGS. 1A˜1F illustrate, in cross section, the fabrication process of a shallow trench isolation structure in one embodiment according to the present invention; and

FIGS. 2A˜2G illustrate, in cross section, the fabrication process of a shallow trench isolation structure in another embodiment according to the present invention; and

FIG. 3 illustrates, in cross section, a seam formed in conventional HDP deposition of a STI structure.

### DETAILED DESCRIPTION OF THE INVENTION

### EXAMPLE 1

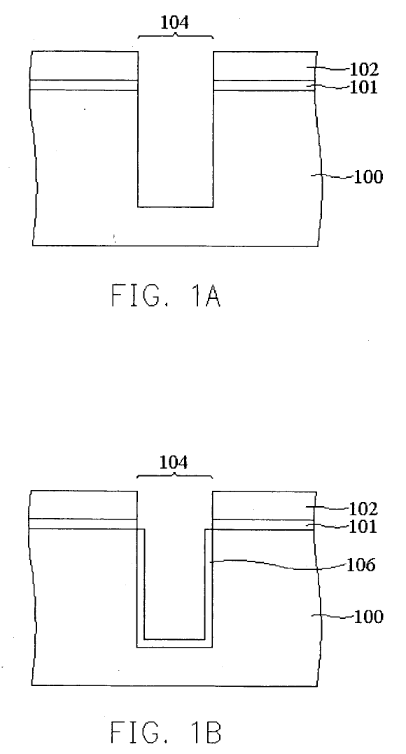

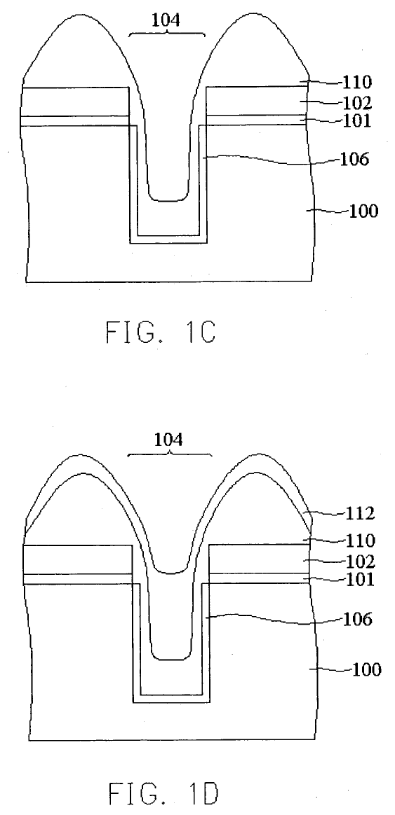

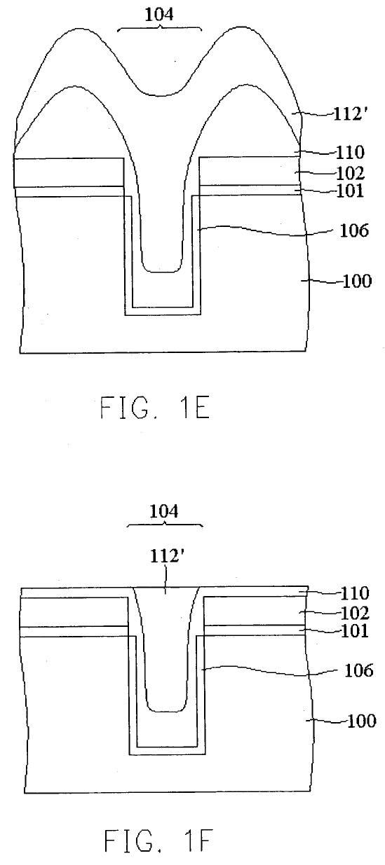

FIGS. 1A˜1G illustrate, in cross section, the fabrication process of a shallow trench isolation structure in one embodiment according to the present invention.

As shown in FIG. 1A, a pad oxide layer 101 is formed over the surface of a semiconductor silicon substrate 100 by thermal oxidization. A nitride layer (SiN) 102 is formed by low pressure CVD (LPCVD) over the pad oxide 101. A photoresist layer (not shown) is patterned by photolithography to form a certain pattern corresponding to the subsequently formed trench on the nitride layer 102. The nitride layer 102 is etched with the patterned photoresist layer as a mask to form a patterned nitride 102 as a hard mask. A shallow trench isolation structure 104 is formed in the silicon substrate 100 by reactive ion etching (RIE) with the silica nitride 102 as the hard mask.

In FIG. 1B, the silicon substrate 100 is subjected to thermal oxidation to grow a liner oxide layer (SiO₂) 106 on the bottom and sidewall of the trench 104. The thermal oxidation can be wet thermal oxidation performed in a oxygen-hydrogen-containing atmosphere at 800 to 850° C., or dry thermal oxidation performed in an oxygen-containing atmosphere at 900 to 950° C. for 2 hours. The inner silicon of the trench 104 is oxidized by the thermal oxidation to form the liner oxide 106 with a thickness of 100˜200 Å.

After the liner oxide layer 106 is grown on the inside of the trench 104, an oxide layer 110 is deposited conformally to fill a portion of the trench 104 as an insulating layer, e.g. undoped silicate glass (USG) formed by high density plasma chemical vapor deposition (HDPCVD), as shown in FIG. 1C.

In FIG. 1D, a poly-silicon layer 112 is deposited conformally over the HDP-USG 110. Preferably, the poly-silicon layer 112 is an amorphous silicon deposited by low pressure chemical vapor deposition (LPCVD) at low temperature (e.g. below 575° C.). The preferred filling thickness of the poly-silicon layer 112 is to almost the surface of the substrate 100.

The silicon substrate 100 is then subjected to a thermal treatment to oxidize the poly-silicon layer 112 at high temperature. Preferably, the silicon substrate 100 is subjected to a thermal oxidation furnace to be oxidized at high temperature and the thickness of the poly-silicon will approximately double as shown in FIG. 1E. Poly-silicon is good in gap filling but poor in isolation quality. However, after the thermal oxidation, the poly-silicon layer 112 is become an oxide layer 112′ providing sufficient insulating capability for STI structure. Also, after the poly-silicon layer is oxidized, an even and uniform insulating oxide is formed, and there will be no voids or seams formed in the trench.

Finally, the surface of the silicon substrate 100 is planarized by chemical mechanical polishing (CMP) to form a well-filled trench 104 as FIG. 1F shows.

### EXAMPLE 2

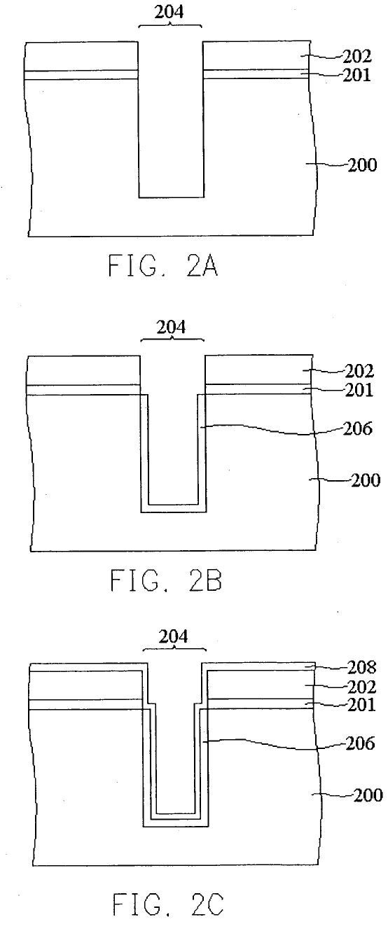

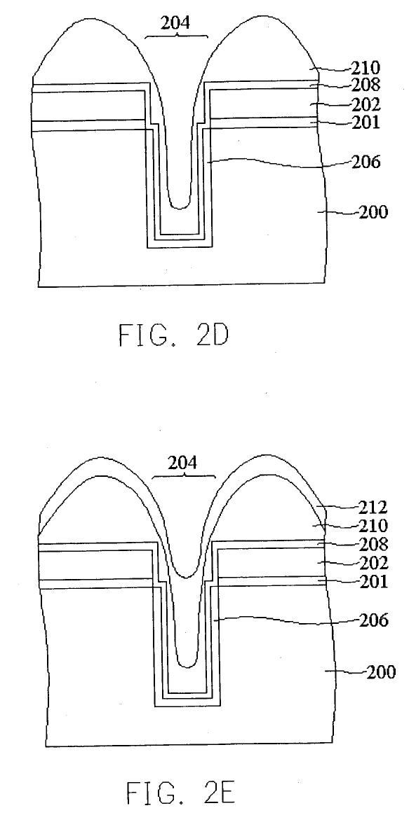

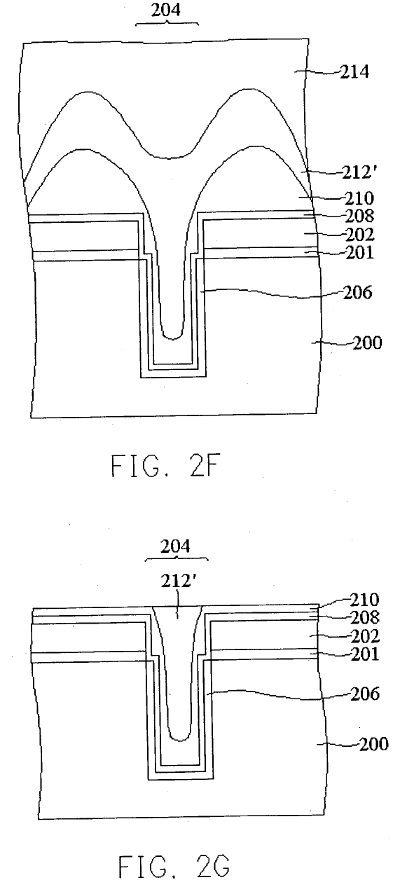

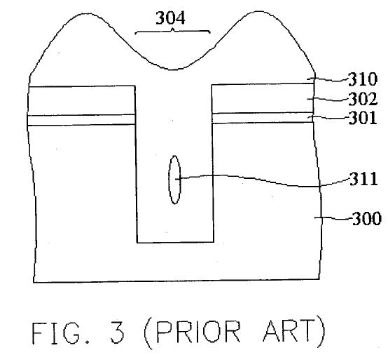

FIGS. 2A˜2G illustrate, in cross section, the fabrication process of a shallow trench isolation structure in another embodiment according to the present invention.

As shown in FIG. 2A, a pad oxide layer 201 and a nitride layer (SiN) 202 are formed subsequently over the surface of a semiconductor silicon substrate 200 by thermal oxidization and LPCVD respectively. A photoresist layer (not shown) is patterned by photolithography to form a certain pattern corresponding to the subsequently formed trench on the nitride layer 202. The nitride layer 202 is etched with the patterned photoresist layer as a mask to form a patterned nitride 202 as a hard mask. A shallow trench isolation structure 204 is formed in the silicon substrate 200 by reactive ion etching (RIE) with the silica nitride 202 as the hard mask.

In FIG. 2B, the silicon substrate 200 is subjected to thermal oxidation to grow a liner oxide layer (SiO₂) 206 on the bottom and sidewall of the trench 204. The thermal oxidation can be wet thermal oxidation performed in a oxygen-hydrogen-containing atmosphere at 800 to 850° C., or dry thermal oxidation performed in an oxygen-containing atmosphere at 900 to 950° C. for 2 hours. The inner silicon of the trench 204 is oxidized by the thermal oxidation to form the liner oxide 206 with a thickness of 200˜200 Å.

After the liner oxide layer 206 is grown on the inside of the trench 204, a nitride layer (SiN) 208 is formed over the liner oxide layer 206 in the trench 204 and the nitride layer 202 to protect the profile of the trench 204, as FIG. 2C shows. The nitride layer 208 protects the silicon substrate 200 from damage by the subsequent oxidation. The dense nitride layer 208 can stop oxygen penetration effectively.

After the liner oxide layer 206 and the liner nitride 208 are grown on the inside of the trench 204, an oxide layer 210 is deposited conformally to fill a portion of the trench 204 as an insulating layer, e.g. undoped silicate glass (USG) formed by high density plasma chemical vapor deposition (HDPCVD), as shown in FIG. 2D. As well as filling the bottom portion of the trench 204, the HDP-USG 210 also provides good protection for the silicon substrate 200 from damage in the subsequent thermal oxidation as the liner nitride 208 does.

In FIG. 2E, a poly-silicon layer 212 is deposited conformally over the HDP-USG 210. Preferably, the poly-silicon layer 212 is an amorphous silicon deposited by low pressure chemical vapor deposition (LPCVD) at low temperature (e.g. below 575° C.). The preferred filling thickness of the poly-silicon layer 112 is to almost the surface of the substrate 200.

The silicon substrate 200 is then subjected to a thermal treatment to oxidize the poly-silicon layer 212 at high temperature. Preferably, the silicon substrate 200 is subjected to a thermal oxidation furnace to be oxidized at high temperature and the thickness of the poly-silicon will approximately double as shown in FIG. 2F. After the thermal oxidation, the poly-silicon layer 212 becomes an oxide layer 212′ providing sufficient insulating capability for STI structure. Also, after the poly-silicon layer 212 is oxidized, an even and uniform insulating oxide 212′ is formed, and there will be no voids or seams formed in the trench 204.

Preferably, one more oxide layer 214 is deposited over the oxidized poly-silicon layer 212′ to provide sufficient thickness and a flat surface for the following planarization as shown in FIG. 2E. The preferred oxide layer 214 is the same as the oxide layer 210, i.e. undoped silicate glass (USG) formed by high density plasma chemical vapor deposition (HDPCVD).

Finally, the surface of the silicon substrate 200 is planarized by chemical mechanical polishing (CMP) to form a well-filled trench 204 as FIG. 2E shows.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method of fabricating a shallow trench isolation structure in a semiconductor substrate, comprising steps of:
forming a trench in the semiconductor substrate;
forming a liner oxide on the bottom and sidewall of the trench;
forming a liner nitride on the liner oxide;
depositing an oxide layer in the trench conformally to fill a portion of the trench by high density plasma chemical vapor deposition (HDPCVD);
depositing a layer of poly-silicon over the oxide layer conformally;
subjecting the semiconductor substrate to a thermal treatment to oxidize the poly-silicon; and
planarizing the surface of the semiconductor substrate.

2. The method as claimed in claim 1, wherein the silicon layer is poly-silicon.

3. The method as claimed in claim 2, wherein the silicon layer is an amorphous poly-silicon layer deposited by chemical vapor deposition at low temperature.

4. The method as claimed in claim 1, wherein the semiconductor substrate is subjected in a furnace to the thermal treatment to oxidize the silicon.

5. The method as claimed in claim 1, wherein the oxide layer in the trench is undoped silicate glass (USG) deposited by the high density plasma chemical vapor deposition (HDPCVD).

6. The method as claimed in claim 1, further comprising a step of depositing an insulating layer over the oxidized poly-silicon.

7. The method as claimed in claim 6, wherein the insulating layer is undoped silicate glass (USG) deposited by high density plasma chemical vapor deposition (HDPCVD).

8. The method as claimed in claim 1, wherein planarizing the surface of the semiconductor substrate uses chemical-mechanical polishing.

9. A method of fabricating a shallow trench isolation structure in a semiconductor substrate, comprising steps of:
forming a trench on the semiconductor substrate;
forming a liner oxide on the bottom and sidewall of the trench;
depositing an oxide layer in the trench conformally to fill a portion of the trench by high density plasma chemical vapor deposition (HDPCVD);
depositing a layer of poly-silicon over the oxide layer conformally;
subjecting the semiconductor substrate to a thermal treatment to oxidize the poly-silicon; and
planarizing the surface of the semiconductor substrate.

10. The method as claimed in claim 9, further comprising a step of forming a liner nitride over the liner oxide.

11. The method as claimed in claim 9, wherein the poly-silicon is amorphous poly-silicon deposited by chemical vapor deposition at low temperature.

12. The method as claimed in claim 9, wherein the semiconductor substrate is subjected in a furnace for the thermal treatment to oxidize the poly-silicon.

13. The method as claimed in claim 9, wherein the oxide layer in the trench is undoped silicate glass (USG) deposited by the high density plasma chemical vapor deposition (HDPCVD).

14. The method as claimed in claim 9, further comprising a step of depositing an insulating layer over the oxidized poly-silicon.

15. The method as claimed in claim 14, wherein the insulating layer is undoped silicate glass (USG) deposited by high density plasma chemical vapor deposition (HDPCVD).

16. The method as claimed in claim 9, wherein planarizing the surface of the semiconductor substrate uses chemical-mechanical polishing.
